(19) United States
(12) Patent Application Publication
(10) Pub. No.: US 2019/0324157 A1
(43) Pub. Date: Oct. 24, 2019

(54) ROD LENS ARRAY COUPLED LINEAR RADIATION DETECTOR WITH RADIATION COMING FROM A SIDE DIRECTION OF SCINTILLATING MATERIAL

(71) Applicant: Linbo Yang, Pleasanton, CA (US)

(72) Inventor: Linbo Yang, Pleasanton, CA (US)

(21) Appl. No.: 16/199,146

(22) Filed: Nov. 24, 2018

Related U.S. Application Data
(60) Provisional application No. 62/612,609, filed on Dec. 31, 2017.

(51) Int. Cl. G01T 1/20; H01L 27/146

(52) U.S. Cl. CPC G01T 1/2002; H01L 27/14629; H01L 27/14663; G01T 1/2018

(57) ABSTRACT

A linear radiation detector array system that is based on a unique focusing principle reduces or eliminates the X-ray radiation damage on the electrical components of the detector system. The system includes a layer of scintillating material, a rod lens array, and an array of image sensors. The layer of scintillating material, such as Gd₂O₂S:Tb (GOS or GADOX), CsI(TI), CdWO₄, or GAGG:Ce is placed on an image plane and is used to convert the impinging radiation energies into visible light which can be detected efficiently by the image sensor array. The rod lens array is used to transmit and focus the visible light after the radiation flux has been converted. The photon energy of the visible light is collected with a scanning image sensor array.

### BACKGROUND OF THE INVENTION

### Field of the Invention

The present invention pertains generally to the field of radiation solid-state imagers and displays, and more particularly is an improved method that structurally alters the optical path to reduce or avoid radiation damage to the semiconductor components while maintaining overall relative high sensitivity.

### BACKGROUND OF THE INVENTION

Image sensor arrays of indirect conversion are usually only sensitive to light with wavelengths at or near the visible spectrum.

Therefore, the arrays require an X-ray-to-visible-light converter in order to detect the X-rays or other radiation. To this end, X-ray sensitive scintillating materials, such as the Gd₂O₂S:Tb (GOS or GADOX), CsI(TI), CdWO₄ or GAGG:Ce have been used.

These materials greatly enhance the detection efficiency of higher energy X-rays in the image sensor arrays through the ability of the scintillating materials to scintillate and emit visible light photons proportional to the X-ray energy. The visible light photons are converted to electrical signals by an image sensor array, such as a Linear Diode Array (LDA). When the image sensor array is read out, the array sequentially produces a stream of electrical video signals from each photo-element with amplitudes proportional to the intensity of the X-ray pattern that impinges on the photo-elements.

There are three major ways to transmit the light from the scintillating materials to a LDA to form an image: 1. by direct coupling; 2. by a fiber optical plate (FOP); 3. by a rodlens array.

Direct coupling is by far the most efficient way, but it also makes LDA on-axis of X-ray path and therefore the most susceptible to radiation damages.

FOP is the next efficient way. It could make LDA either on-axis or off-axis. When X-ray energy is relatively low, on-axis FOP can protect LDA to some extent. However, when X-ray energy is relatively high, use of off-axis FOP would become necessary. FOP is usually very expensive, large scale use of FOP at high energy X-ray application might not be cost effective.

Rod Lens array is a low cost alternative to the FOP. It provides the novel non-touching way to transmit the light from the scintillating materials to a LDA to form an image. It was originally introduced for an application like that in a desktop fax, copy, scanner machine. Functioning just like a single lens, a rod Lens array transfers an image from one image plane at one side of a lens to another side of the lens.

In prior arts that use rodlens, the scintillating materials are placed on an optical transmission plate, such as a piece of glass, plastic etc. Other optical components are also suggested like optical transmission pin, such as a prism; an optical path reflector, such as a mirror.

However, problems arise in the prior arts.

The first disadvantage of prior arts is substantial light loss. Due to much smaller solid angle at rodlens array compared with that at FOP, rodlens arrays would have much more light loss than that at FOP. But it is well known fact that using FOP would result in much smaller signal than that at Direct Coupling. Therefore, great care has to be taken to preserve the light transmission efficiency in order to make rodlens arrays to be useful in an application. When light travel from one media to another media, reflect will occur at both in and out surfaces. As a result, less optical components on the light path will have higher transmission efficiency.

The second disadvantage of prior arts is that, qualitatively, if an optical transmission plate is placed between rodlens and focal spot, the overall optical system focal length would be changed just like that in a single lens system. Image quality would largely depend on if a good focusing can be achieved. The problem of focal length changes is not suggested in the prior arts.

The third disadvantage of prior arts is that, quantitatively, the change of system focal length would not only depend on the geometrical size of the optical transmission plate or optical transmission pin but also depends on the nature of optical plate or pin material its self because different optical material would have different index of refraction.

The fourth disadvantage of prior arts is that it would introduce a complicated two dimensional focusing process. Both mirror and prism will change optical path. In practice, trying to perform 2D both X and Y direction focusing is time-consuming.

The fifth disadvantage of the prior arts is that, usually a high quality piece of long single piece narrow plate, mirror or prism is required in order to meet the performance requirements. This kind of high precision long, narrow mirror or prism is not only very expensive, but also there is a limit of max length that a manufacturer can produce.

The sixth disadvantage of the prior arts is that, if there are no long pieces of mirror or prism available, then cascade of multiple shorter pieces would be necessary. As a result, gaps between each plate, mirror or prism are inevitable. The sizes of the gaps are usually very difficult to control.

The seventh disadvantage of the prior arts is that a plate, a mirror or a prism is usually in a radiation path, and this kind of optical components tends to turn brown or yellow after receiving certain amount of X-ray doses so that light transmission efficiency will be seriously affected. When the browning becomes so severe it would make the whole optical system unusable. In other words, there is a finite lifetime on a plate, a mirror or a prism under X-ray.

The eighth disadvantage of the prior arts is that, practically, only rodlens with relatively longer focal length can be used. Just like that at zoom lens, there will be even more light loss at a long focal length system compared with that in a shorter focal length. Usually available focal lengths of rodlens are usually from about several mm to tens of mm. In real fabrication practice, there is always a minimum size required for making plate, mirror or prism in order to put between rodlens and focal spot. Imager also need some space to mount nearby a rodlens. As a result, prior arts can only choose to use rodlens with relatively longer focal length that will make system less sensitive.

The ninth disadvantage of the prior arts is that, in practice, longer piece of glass tend to be brittle and easy to break so that whole system becomes unusable. If an X-ray detector system is equipped with this kind of optical components, a small accidental drop of package during the shipping will cause damage of optical components. As a result, its reliability is very low.

The tenth disadvantage of the prior arts is that, in practice, long narrow optical components are very difficult to handle. It also has safety hazard. It is always possible for glass of sharp edges cause injury of finger cut.

In view of many disadvantages, so far commercial viability of prior arts has been minimal.

Accordingly, it is an object of the present invention to address those listed issues and provide an detector that is sensitive, compact, long life, low cost and easy to assemble.

### SUMMARY OF THE INVENTION

A key feature of the present invention is the utilization of the one-to-one imaging characteristics of a rod lens array to achieve good resolution in the radiation (X-ray, Gamma-ray, neutron for example) detector system while keeping simplicity, maintaining higher light transmission efficiency and reducing manufacture cost.

The present invention is a radiation damage resistant linear X-ray detector array system. The detector array system is based on a unique focusing principle using the rod lens array. The simple system includes a scintillating material layer, the rod lens array, and an array of image sensors. Some of the viable options for the scintillating material are Gd₂O₂S:Tb (GOS or GADOX), CsI(TI), CdWO₄ and GAGG:Ce.

For linear radiation detector array system, radiation coming-in direction is not from top of scintillating material, but rather coming from a side or from an angle.

The scintillating materials layer is placed on an image plane and is used to convert the impinging X-ray energies into visible light which can be detected efficiently by an image sensor array. The rod lens array is used to focus the visible light after the X-ray flux has been converted. The photon energy of the visible light is collected with a scanning image sensor array that converts the photon energy proportionally into electrical video signals and enables it to be processed using standard signal and image processing software and equipment.

Utilization of the rod lens array enables the user of the present invention to isolate or shield the radiation sensitive semiconductor components from radiation exposure in a detector system.

Advantage of using the rod lens array in an X-ray detector system is its physical structure. The rod lens array is a single solid piece with an array of optical transmission rods with fixed focus. This enables the rod lens array to be easily installed with little or no positional adjustments, thereby yielding an X-ray system that can be easily implemented with little or no optical adjustments, as opposed to the many adjustments required for a fiber optical coupled system.

Another advantage of the present invention is that the existing low-cost and high-volume production of the rod lens arrays allows the X-ray detector machines according to the present invention to also be produced at low cost and high volume.

Another advantage of the present invention is that focal length is constant in the air and one dimensional focusing procedure is simple.

Another advantage of the present invention is that it makes it possible to manufacture a small, portable X-ray detector machine.

Another advantage of the present invention is that most of time this invention is for high energy X-ray application, in this case a thicker scintillating materials layer is needed. It is easier to make fixture to hold scintillating material layer without considering optical plate.

Yet another advantage of the present invention is that with the small enclosure size required and the methods of radiation shielding, it is possible to design dual or multi X-ray scanning machines enclosed in the same space currently used to enclose a single X-ray scanning machine. The dual or multi X-ray scanning machines can be used for scanning a target simultaneously in different X-ray energy ranges for better detection.

Still another advantage arising from the small size and shielding properties of the present invention is that it is possible to implement a three-dimensional X-ray scanner, in which two scanning detectors system are positioned orthogonally with respect to each other.

Another advantage arises from the focusing ability of the rod lens array. The rod lens array has a resolution capability much higher than that of the scintillating material, and therefore is not the limiting factor in the system resolution.

Another advantage, arising from the direct focusing of the system is that it keeps light energy loss to a minimum. The only losses are the transmission attenuation of the rod lens itself.

Another advantage, arising from the fact that detector pixel prospect radio and scintillating material efficiency is adjustable by either rod lens orientation relative to X-ray beam or by shielding slit width.

One additional advantage is that the scintillating materials utilized, Gd₂O₂S:Tb (GOS or GADOX), CsI(TI), CdWO₄ and GAGG:Ce are easily interchangeable or even repairable if users want to swap among them in order to implement X-ray detection with a different energy range and efficiency.

If scintillating material is thin it is always possible to attached scintillating material to a light weight support plate (carbon fiber plate, Aluminum plate for example) at the top of scintillating material so that radiation can go through while light transmission efficiency is preserved.

It should be mentioned that the linear detector also works with other radiation source like gamma ray and neutron when an appropriate type of scintillation material is applied.

A pixel at a linear detector could have various prospect ratio so it is possible for X-ray to come in from side of scintillation material.

### BRIEF DESCRIPTION OF THE DRAWINGS

FIG. 1 shows a typical application in which the detection elements of the system are rotated slightly to allow the image sensor array to be away from the X-ray flux path.

FIG. 2 illustrates the typical rod lens array used in the present invention.

FIG. 3 shows an application in which the X-ray flux enters scintillation material from the side.

FIG. 4 shows an application in which the detection elements of the system are away from the X-ray flux path and are at the backward side.

FIG. 5 shows an application in which the scintillation material layer is relatively thin.

### DETAILED DESCRIPTION OF THE PRESENT INVENTION

The present invention is a linear X-ray detector system 1.

The detector system 1 is based on a unique focusing principle that utilizes a rod lens array 5.

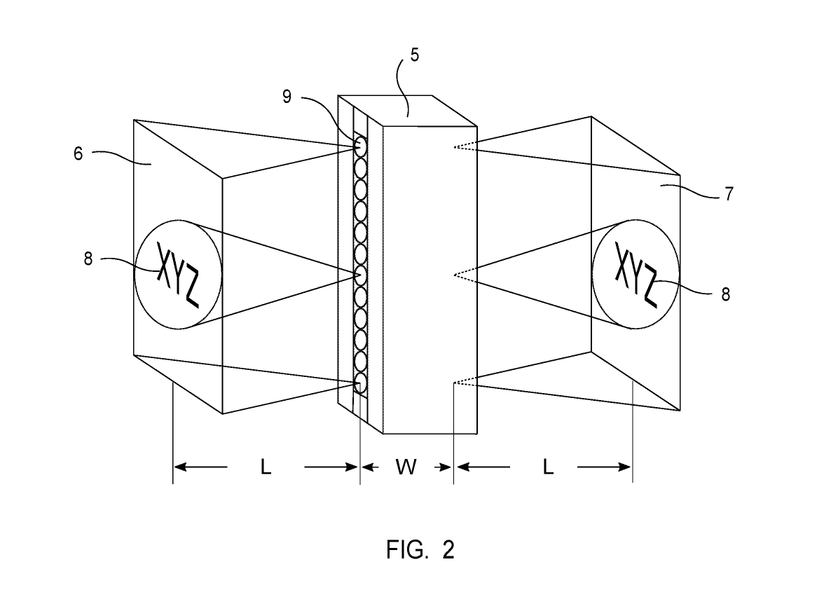

A typical rod lens array 5 is illustrated in FIG. 2. Selections of rod lens include commercially available single row and dual row rod lens.

The X-ray detector system 1 comprises scintillating material 14, a rod lens array 5 and image sensor array 15. In light pass, there is no other unnecessary optical media like optical glue, glass, plastics, plate, prism, mirror etc in order to preserve light transmission with high efficiency.

Some of the viable options for the scintillating material are Gd₂O₂S:Tb (GOS or GADOX), CsI(TI), CdWO₄, or GAGG:Ce etc.

Scintillating material 14 is placed in an object image plane 6 and is used to convert the impinging X-ray energies into visible light which can be detected by the image sensor array 15 in image plane 7.

There is also shielding material 12 and slit aperture 13 to safeguard electronics and reduce scatter. The size of slit aperture 13 would largely depend on pixel size of image sensor.

A rod lens array 5 is acting bidirectional. There are a pairs of image planes. One is object image plane 6, other is image plane 7. Finite focal length is at both sides, there is finite width of rod lens for a rod lens array. If scintillating material 14 is located at object image plane 6 then image sensor array 15 is located in image plane 7 and vice versa. Object and image are with 1:1 ratio.

Exact replica of the image which is illuminated in object image plane 6 will be created in image plane 7.

Essentially, image at scintillating material 14 created by radiation will be reproduced at image sensor array 15 though a rod lens array 5.

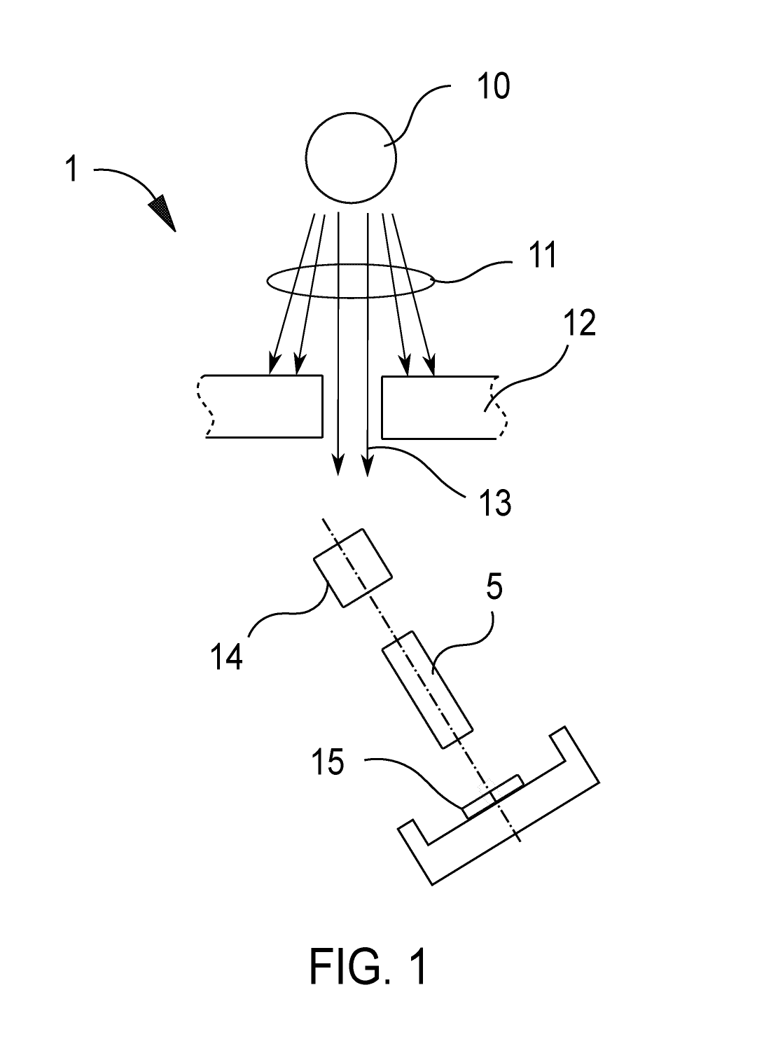

FIG. 1 shows an implementation of typical linear X-ray detector system 1 with image sensor array at forward direction. This is the most popular off-axis configuration with tiled angle. In this configuration, scintillation material 14 has a tilted angle so that image sensor is completely off the X-ray path axis, commonly referred as off-axis. Tilted angle, off-axis configuration in linear detector has been used commercially in high energy application.

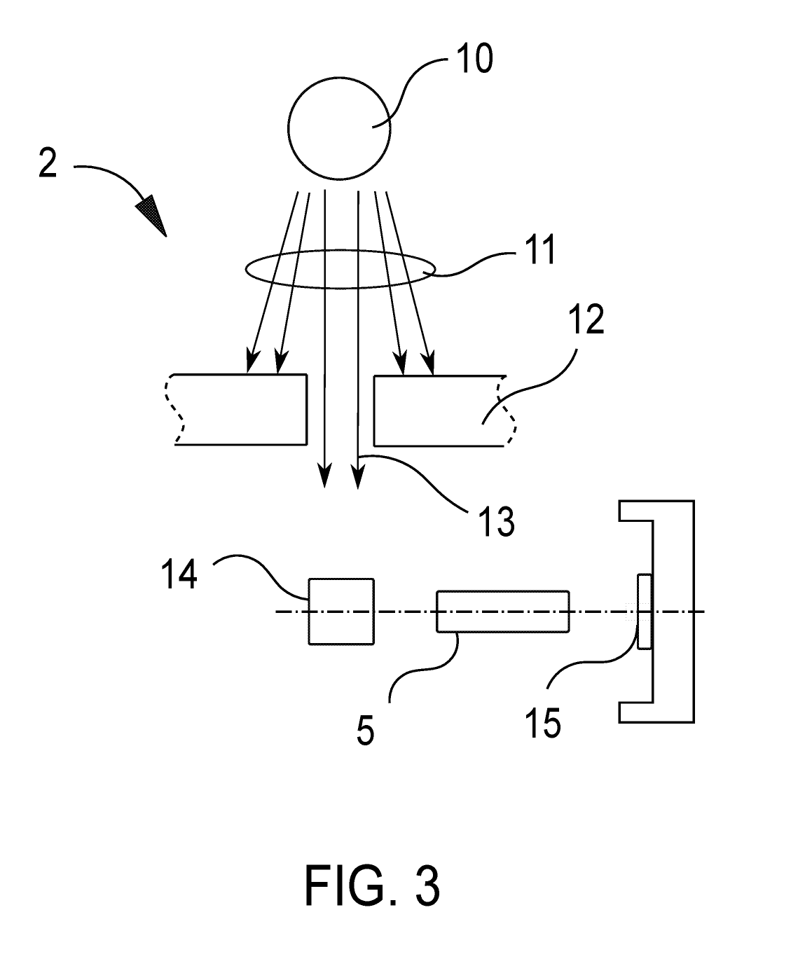

FIG. 3 shows a modified implementation of X-ray detector system 2 with image sensor array 15 being perpendicular to X-ray beam direction. This configuration makes it easier to install components mechanically. It is suitable for linear X-ray detector with slightly larger pixel size with thicker scintillating material. In this case, most of time, scintillating material itself is pixilated, so actual imaging pixel size is determined by scintillating material cross-section that is facing X-ray beam.

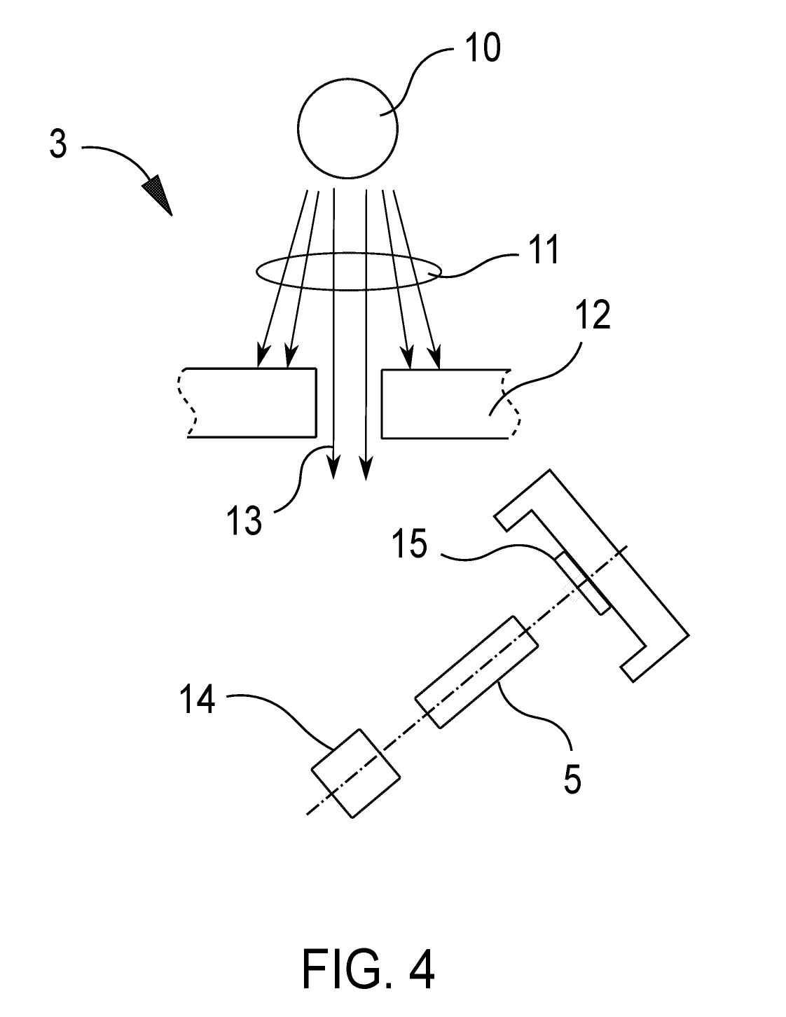

FIG. 4 shows another implementation of X-ray detector system 3 with image sensor array at backward direction relative to X-ray beam. Advantage of this configuration is that it can reduce scatter even more because most of scattered X-ray goes to forward direction.

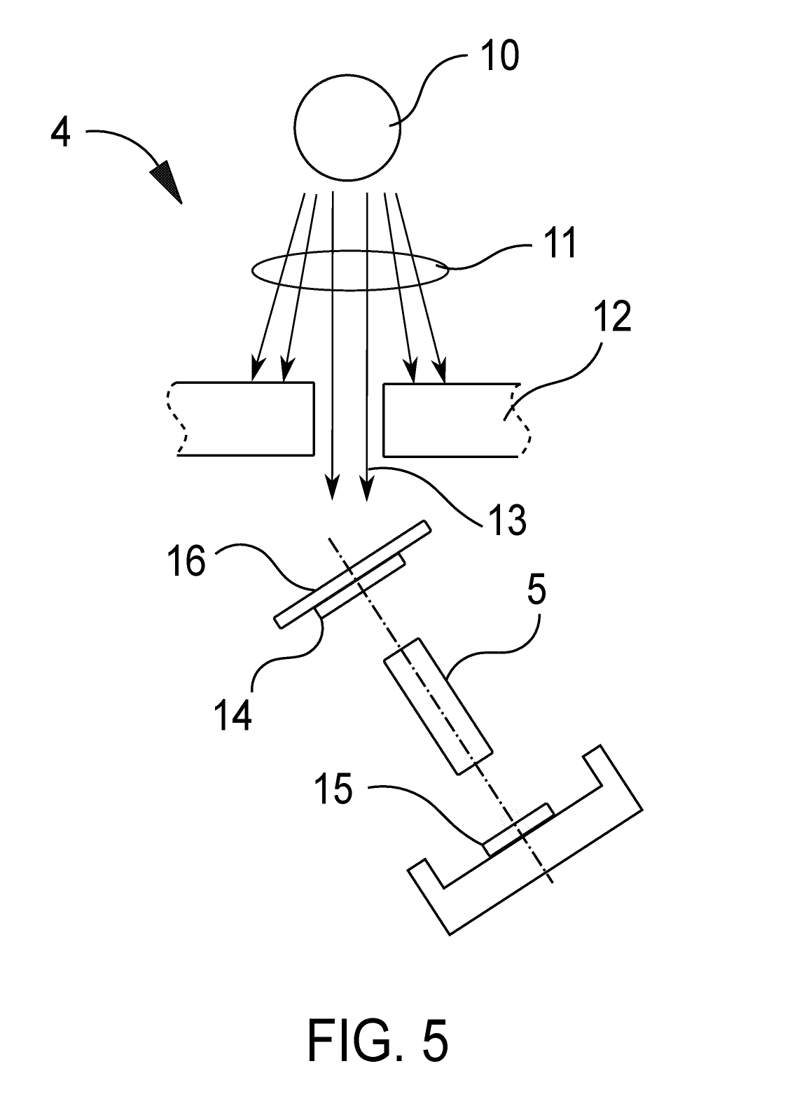

FIG. 5 shows still another implementation of X-ray detector system 4 for a relatively thin layer of scintillating material 14. There are various kinds of light-weighted material available like carbon fiber plate and thin aluminum plate that is able to support scintillating material 14. Those light-weighted materials are X-ray transparent in most cases.

Backside of thin scintillating material 14 is attached to the supporting plate as light-weight holder 16. For example, GOS scintillating material substrate can be glued on light-weight holder 16. There are no other objects at light pass between scintillating material 14 and rod lens array 5. Therefore, light transmission efficiency is preserved.

The above disclosure is not intended as limiting. Those skilled in the art will readily observe that variations and alterations of the device may be made while retaining the teachings of the invention. Accordingly, the above disclosure should be construed as limited only by the restrictions of the following claims.

I claim:

1. An radiation detector system comprising:
a scintillating material layer,
a rod lens array, and
an image sensor array; wherein
when a test specimen is exposed to an radiation beam from an radiation source, said radiation beam passes through the test specimen, enters said scintillating material layer from a side and excites said scintillating material layer proportionally to radiation density patterns of the test specimen, and
a converted optical image from said scintillating material layer is focused by said rod lens array onto said image sensor array, a reproduced image of the test specimen thereafter being read out of said image sensor array; and wherein
an optical path passing directly through said rod lens array, and said image sensor array is offset by an angle relative to a centerline of a radiation flux path from said radiation source, such that detecting components of said radiation detector system are located away from said radiation flux path.

2. The radiation detector system as defined in claim 1 wherein:
a lead or tungsten shield with an aperture therein is positioned between said radiation source and the test specimen.
